(19) United States
(12) Patent Application Publication
(10) Pub. No.: US 2019/0164891 A1
(43) Pub. Date: May 30, 2019

(54) TUNABLE DIFFERENTIAL VIA CIRCUIT

(71) Applicant: Finisar Corporation, Sunnyvale, CA (US)

(72) Inventors: Steven C. Bird, San Jose, CA (US); Ron Greenlaw, Sunnyvale, CA (US); Henry Meyer Daghighian, Redwood City, CA (US)

(21) Appl. No.: 15/822,952

(22) Filed: Nov. 27, 2017

(51) Int. Cl. H01L 23/538; H01L 23/66; H01L 31/02

(52) U.S. Cl. CPC H01L 23/5384; H01L 2223/6616; H01L 31/02002; H01L 23/66

(57) ABSTRACT

A circuit of tunable differential vias may include a first tunable via circuit configured to couple a first signal of a differential signal pair from a first outer surface of a printed circuit board (PCB) to a second outer surface of the PCB. The circuit may further include a second tunable via circuit configured to couple a second signal of the differential signal pair from the first outer surface of the PCB to the second outer surface of the PCB. The first tunable via circuit may further include a first buried via spatially offset from the second tunable via circuit to cause a predetermined impedance for the first and second signals through the first and second tunable via circuits at an operating frequency.

### BACKGROUND

### Field

The embodiments discussed herein relate to high-speed circuits. In particular, embodiments relate to circuit boards with differential vias.

### Relevant Technology

Electronic modules, such as optoelectronic transceiver or transponder modules, are increasingly used in electronic and optoelectronic communication. Optoelectronic modules generally include one or more transmitters and/or receivers, as well as one or more printed circuit boards (PCBs) with circuitry related to the transmitters/receivers, such as driving and amplifying circuitry. Electrical data signals generally pass through this circuitry as they pass between the transmitters/receivers and a host device in which the optoelectronic module may be positioned.

It is desirable for optoelectronic communications to send and receive data signals having ever higher frequencies in order to increase the rate at which data may be communicated via the optoelectronic modules. However, increasing data signal frequencies may present a number of difficulties in designing optoelectronic modules. In particular, increasing data signal frequencies may lead to signal degradation in circuits designed using techniques otherwise acceptable for lower data signal frequencies.

Broadband communication devices, specifically those operating at frequencies greater than 25 GHz, rely on multilayer printed circuit boards (PCBs) for interconnection and routing of signals between components. This interconnection and routing of signals results in routes that include signal paths traversing multiple layers within the PCB. These multiple layers are coupled together using vias. Routing of signals between layers, and particularly between the top and bottom layers of a PCB, compromises the signal integrity due to the routing transitions between layers and the associated impedance changes related to the transitions. Since multiple communication channels may be generated by the circuitry on a PCB, interconnections to the multiple channels may be distributed over both sides of the PCB resulting in the necessity for vias to route signals to an opposing side of the PCB. Accordingly, management of the impedances associated with the vias becomes important.

The subject matter claimed herein is not limited to embodiments that solve any disadvantages or that operate only in environments such as those described above. Rather, this background is only provided to illustrate one exemplary technology area where some embodiments described herein may be practiced.

### SUMMARY

Embodiments described herein generally relate to systems for transmission of high-speed signals. In particular, embodiments may relate to circuit boards with differential signals passing from one side of the circuit board to another side of the circuit board.

This Summary is provided to introduce a selection of concepts in a simplified form that are further described below in the Detailed Description. This Summary is not intended to identify key features or essential characteristics of the claimed subject matter, nor is it intended to be used as an aid in determining the scope of the claimed subject matter.

In one embodiment, a circuit includes a first tunable via circuit configured to couple a first signal of a differential signal pair from a first outer surface of a printed circuit board (PCB) to a second outer surface of the PCB. The circuit may further include a second tunable via circuit configured to couple a second signal of the differential signal pair from the first outer surface of the PCB to the second outer surface of the PCB. The first tunable via circuit may further include a first buried via spatially offset from the second tunable via circuit to cause a predetermined impedance for the first and second signals through the first and second tunable via circuits at an operating frequency.

In another embodiment, a circuit may include a multilayer rigid flex PCB including a first cap layer forming a first outer surface of the multilayer rigid flex PCB and a second cap layer forming a second outer surface of the multilayer rigid flex PCB. The circuit may further include tunable differential vias formed between the first and second outer surfaces of the multilayer rigid flex circuit. The tunable differential vias may include a first tunable via circuit configured to couple a first signal of a differential signal pair from the first outer surface of the multilayer rigid flex PCB to a second outer surface of the multilayer rigid flex PCB. The tunable differential vias may further include a second tunable via circuit configured to couple a second signal of the differential signal pair from the first outer surface of the multilayer rigid flex PCB to the second outer surface of the multilayer rigid flex PCB. The first tunable via circuit including a first buried via spatially offset from the second tunable via circuit to cause a predetermined impedance for the first and second signals through the first and second tunable via circuits at an operating frequency.

In another embodiment, an optoelectronic module may include an optical transmitter, an optical receiver, and a circuit including a printed circuit board (PCB). The printed circuit board may include a first tunable via circuit configured to couple a first signal of a differential signal pair from the first outer surface of the multilayer rigid flex PCB to a second outer surface of the multilayer rigid flex PCB. The printed circuit board may further include a second tunable via circuit configured to couple a second signal of the differential signal pair from the first outer surface of the multilayer rigid flex PCB to the second outer surface of the multilayer rigid flex PCB. The first tunable via circuit including a first buried via spatially offset from the second tunable via circuit to cause a predetermined impedance for the first and second signals through the first and second tunable via circuits at an operating frequency.

In a further embodiment, a method includes forming a first tunable via circuit configured to couple a first signal of a differential signal pair from a first outer surface of a printed circuit board (PCB) to a second outer surface of the PCB. The method further includes forming a second tunable via circuit configured to couple a second signal of the differential signal pair from the first outer surface of the PCB to the second outer surface of the PCB. The first tunable via circuit including a first buried via spatially offset from the second tunable via circuit to cause a predetermined impedance for the first and second signals through the first and second tunable via circuits at an operating frequency.

Additional features and advantages of the invention will be set forth in the description which follows, and in part will be obvious from the description, or may be learned by the practice of the invention. The features and advantages of the invention may be realized and obtained by means of the instruments and combinations particularly pointed out in the appended claims. These and other features of the present invention will become more fully apparent from the following description and appended claims, or may be learned by the practice of the invention as set forth hereinafter.

### BRIEF DESCRIPTION OF THE DRAWINGS

To further clarify the above and other advantages and features of the present invention, a more particular description of the invention will be rendered by reference to specific embodiments thereof which are illustrated in the appended drawings. It is appreciated that these drawings depict only typical embodiments of the invention and are therefore not to be considered limiting of its scope. The invention will be described and explained with additional specificity and detail through the use of the accompanying drawings in which:

FIG. 1 illustrates a first perspective view of an example optoelectronic module;

FIG. 2 is the cross-sectional view of the rigid flex PCB;

FIG. 3 illustrates a perspective view of a portion of the optoelectronic module of FIG. 1;

FIG. 4 is a cross-sectional view of tunable differential vias;

FIG. 5 illustrates an example geometry of the electromagnetic field relationship and method of calculating the resultant impedance for the tunable differential vias; and

FIG. 6 is a flowchart of an example method of manufacturing the example tunable differential vias.

### DESCRIPTION OF EMBODIMENTS

One problem with traditional dual-side connector rigid flex PCBs is that ordinary rigid flex PCB design techniques may be used to create optoelectronic circuits for only relatively low-speed data transmission frequencies. However, as data signal frequencies increase, using ordinary rigid flex PCB design techniques to create a high-speed optoelectronic circuit results in unacceptable signal degradation. For example, signal degradation may occur due to feed-through vias, transmission line interconnects and/or interfaces, and/or low impedance ground connections running from the top of the rigid section to the bottom of the rigid section. As a result, rigid flex PCBs developed using ordinary rigid flex PCB design techniques are typically unsuitable for transmitting signals having data rates above about 25 gigabits per second (Gb/s).

To bring the signal degradation within acceptable levels, a flexible PCB and a rigid ceramic laminate such as a low-temperature co-fired ceramic (LTCC) may be soldered together using ball grid array (BGA) soldering. The ceramic laminate may include high frequency vias, transmission lines, and ground reference interfaces required, while the flexible circuit may be contorted to take advantage of the three-dimensional space within the optoelectronic module. However, such a solution may be expensive and demands significant assembly effort.

As disclosed by embodiments herein, a hybrid or rigid flex circuit suitable for transmitting signals having data rates above 25 Gb/s may be constructed. Rigid flex circuits may be comparatively inexpensive to manufacture and/or may demand a comparatively minimal assembly effort.

Various circuits, modules, systems, and methods are described herein for utilizing a combination of blind vias and buried vias for conveying differential signals from a first side of a PCB to a second side of the PCB. The buried vias are not bound or fixed to a requisite position like conventional through-hole vias. Accordingly, the distance between the buried vias configured for transmission of a differential signal may be spatially adjustable. The adjustability allows the impedance of the differential vias to be changed, for example, to improve or match the characteristic impedance of the transmission lines carrying the differential signals. Accordingly, reflections and mismatches may be minimized.

In one configuration, the tunable differential vias include a first tunable via circuit configured to couple a first signal of a differential signal pair from a first outer surface of a printed circuit board (PCB) to a second outer surface of the PCB, and a second tunable via circuit configured to couple a second signal of the differential signal pair from the first outer surface of the PCB to the second outer surface of the PCB. One of the circuits, for example the first tunable via circuit, includes a first buried via spatially offset from the second tunable via circuit to cause a predetermined impedance for the first and second signals through the first and second tunable via circuits at an operating frequency.

In another configuration, the other or second tunable via circuit may also include a second blind via between the second outer surface of the PCB and the first buried via. The second blind via may be spatially adjusted with respect to the first blind via to generate a predefined or desired characteristic impedance for the tunable differential vias. In other configurations, the blind vias may have shared pads for electrically coupling to either a pin or contact on an electronic component, or a blocking capacitor. The sharing of pads may reduce impedance mismatches resulting from interfaces with, for example, pins or contacts of electronic components and passive components such as blocking capacitors.

Reference will now be made to figures wherein like structures will be provided with like reference designations. It is understood that the drawings are diagrammatic and schematic representations of exemplary embodiments, and are not limiting of the present invention nor are they necessarily drawn to scale.

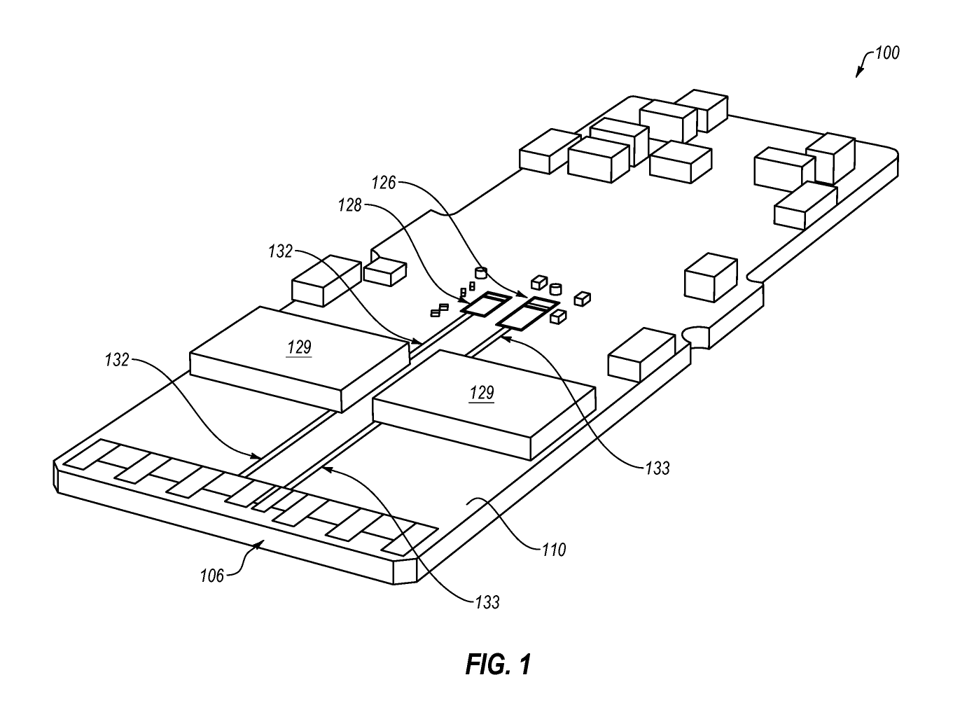

FIG. 1 illustrates a first perspective view of an example optoelectronic module 100. The optoelectronic module 100 may be used to transmit and receive optical signals in communication with one or more other devices on a network and to communicate by way of electrical signals with a host device. The example optoelectronic module 100 may include a rigid flex PCB 110 suitable for transmitting signals having data rates above about 25 Gb/s. Including the rigid flex PCB 110 in the optoelectronic module 100 may lower manufacturing costs for the optoelectronic module 100. The rigid flex PCB 110 may be more cost effective to manufacture than other circuits able to transmit signals having data rates above about 25 Gb/s, particularly compared to other circuits including flexible and rigid sections.

The optoelectronic module 100 may include a transmitter 126 and a receiver 128 for respectively transmitting and receiving optical signals by way of an optical communication cable (not shown) connected to the optoelectronic module 100 by way of an alignment guide (not shown) and a shell (not shown). The optoelectronic module 100 may further include a transmit driver circuit 127 and a receiver circuit 129. While the various embodiments may make reference to optical communication, the various methods and circuits described herein are not so limited.

The optoelectronic module 100 may be configured for optical signal transmission and reception at a variety of data rates. Further, the optoelectronic module 100 may be configured for optical signal transmission and reception at various wavelengths including, but not limited to, 850 nanometers (nm), 1310 nm, 1470 nm, 1490 nm, 1510 nm, 1530 nm, 1550 nm, 1570 nm, 1590 nm, 1610 nm, or longer wavelengths. The optoelectronic module 100 may be configured to support various communication protocols including, but not limited to, INFINIBAND, Fast Ethernet, Gigabit Ethernet, 10 Gigabit Ethernet, Fibre Channel, and SONET. Although the example optoelectronic module 100 may be configured to be substantially compliant with the quad small form-factor pluggable (QSFP) MSA, the optoelectronic module 100 may alternately be configured to comply with a variety of other MSAs that include a rigid pluggable connector. For example, the optoelectronic module 100 may be configured to be substantially compliant with the CXP MSA.

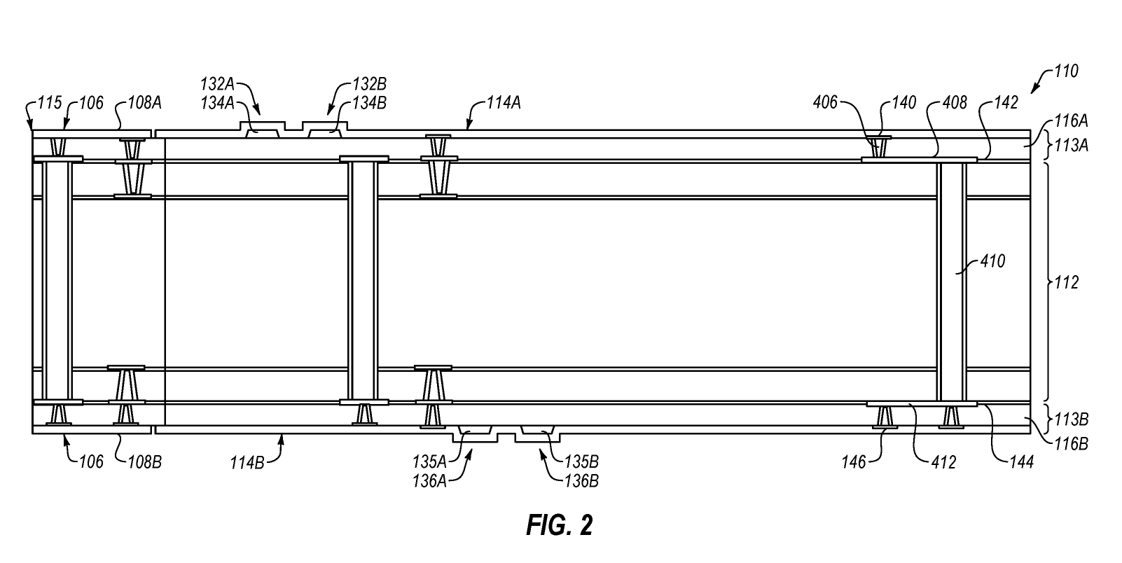

When the optoelectronic module 100 is plugged into a connection interface of a host device, a dual-sided connector 106 may be configured to form a pluggable dual-sided electrically conductive connection with the connection interface of the host device. The dual-sided connector 106 may further allow the host device to physically retain the optoelectronic module 100 until the optoelectronic module 100 is purposefully unplugged from the host device. The dual-sided connector 106 may be formed on an end section of a circuit. The dual-sided connector 106 may be formed on a portion of the rigid flex PCB 110 that includes both of one or more flexible sections (e.g., one or more cap-layers) and a rigid section (e.g., core layers) of a rigid flex PCB 110. The rigid flex PCB 110 may be made from multiple insulating layers, including flexible and rigid layers, as will be described in detail herein with reference to FIG. 2.

Conventional PCBs constructed using glass-reinforced laminate may not be suitable for high speed applications. For example, when a PCB with glass-reinforced laminate operates at a high frequency, significant parasitic capacitance and/or inductance may be incurred by transmission lines in the PCB, which can distort transmitted signals.

The rigid flex PCB 110 described herein may include a set of substrates that enables efficient transmission at a speed equal to or greater than 25 gigabits per second per channel. The efficient transmission may be achieved by a unique combination of wire bondable interconnects to flip-chip mounted die and placement of the flip-chip mounted die at least partially within (i.e., sunken between the exterior surfaces of) the rigid flex PCB 110.

FIG. 2 is the cross-sectional view of the rigid flex PCB 110. The rigid flex PCB 110 includes one or more flexible sections or cap layers 113A and 113B, and a rigid section or core layers 112. The cap layers 113 may be comprised of, for example, a polyimide material, an example of which is DuPont® AP7163 exhibiting a low Dk and Df. The rigid section or core layers 112 may be comprised of, for example, a material of one or more conductive and insulative layers such as FR4 sub-laminate. The cap layers 113 may be attached to the core layers 112 using an adhesive (not shown), an example of which is DuPont® LF7049 adhesive.

The high-frequency unreinforced laminate, namely the cap layer 113, may include a thin sheet of glass-free dielectric material 116 with a thickness, for example, of about 37 or 38 micrometers, with low relative permittivity (low Dk) and low loss tangent (low Df) compared to the reinforced laminate, namely the core layers 112.

By utilizing high-frequency cap layers 113 on the top and/or bottom of the core layers 112, connecting elements with super fine geometries may be constructed on the top side and the bottom side of the rigid flex PCB 110. For example, traces with a trace width between 50 micrometers and 60 micrometers, trace pitches with a pitch width between 100 and 110 micrometers, wire bond pads in a 60-micrometer scale, and BGA pitches smaller than 0.4 millimeter may be constructed on the top side and the bottom side of the rigid flex PCB 110, respectively. As a result, high-density interconnects may be routed on the top side and the bottom side of the rigid flex PCB 110, while low-speed components and power circuits may be routed and/or located in the internal layers of the rigid flex PCB 110.

The dual-sided connector 106 may be respectively formed on faces 114A and 114B of the cap layers 113A and 113B near an edge 115 of the rigid flex PCB 110. The dual-sided connector 106 may form an edge connector for connecting with a host device (not shown). The dual-sided connector 106 may include multiple contacts 108 to form a pluggable dual-sided electrically conductive connection with corresponding contacts (not shown) of a host device. Contacts 108A and 108B may be electrically connected to a ground connection, as illustrated in FIG. 2, while other contacts 108 may be electrically connected to signal transmission lines 132A and 132B (collectively “signal transmission lines 132”) which may be configured as differential signals, or to one or more components (not shown) of the optoelectronic module 100. As illustrated in FIG. 2, the dual-sided connector 106 may include contacts 108B formed on an opposite face 116B on the cap layer 113B of rigid flex PCB 110.

One of the transmitter 126 or the receiver 128 of FIG. 1 may be electrically connected, for example, to signal transmission lines 132A and 132B with the other one of the transmitter 126 or receiver 128 coupled to other signal transmission lines (not shown) on the same face 114 of the rigid flex PCB 110. Further, other transmitters and receivers may be coupled, for example, to the signal transmission lines 136A and 136B. Further, the signal transmission lines 132 and 136 may also be electrically connected to other contacts (not shown) that may be adjacent to contacts 108A and 108B. Preferably, the signal transmission lines 132 and 136 may be controlled-impedance transmission lines. For example, the signal transmission lines 132 and 136 may be controlled-impedance transmission lines with an impedance of 100 ohms.

Although only two pairs of signal transmission lines 132 and 136 are shown, it will be appreciated that more signal transmission lines may be included in the rigid flex PCB 110. For example, in some embodiments, four differential signal transmission lines may be coupled to the transmitter 126 and four differential signal transmission lines may be coupled to the receiver 128. However, another number of signal transmission lines may couple the transmitter 126 and/or receiver 128 to contacts 108. Alternately or additionally, transmission lines may couple other circuitry (not shown) on the rigid flex PCB 110 to contacts 108.

As illustrated, the signal transmission line 132 may be differential signal transmission lines configured to transmit the incoming electrical data signal over a pair of differential conductive signal traces 134A and 134B. The differential conductive signal traces 134A and 134B may be formed on one or more of the insulating layers, for example dielectric layer 116A, of the cap layer 113A. Similarly, the signal transmission lines 136 may be differential signal transmission lines configured to transmit the incoming electrical data signal over a pair of differential conductive signal traces 135A and 135B. The differential conductive signal traces 135A and 135B may be formed on one or more of the insulating layers, for example dielectric layer 116B, of the cap layer 113B.

Surface finishing of the rigid flex PCB may be performed using electroless nickel electroless palladium immersion gold (ENEPIG) or other suitable surface finishing. A surface finish created using an ENEPIG process may be referred to as an ENEPIG surface finish. ENEPIG surface finishes may include an electroless nickel plating covered by an electroless palladium plating covered by a thin layer of immersion gold.

The usage of high-frequency cap layer 113 of unreinforced laminate on the top and/or bottom sections of the rigid flex PCB and the usage of palladium in the surface finish may allow connecting elements with super fine geometries to be deposited on the top side and the bottom side of the hybrid PCB. The super fine connecting elements (e.g., super fine traces with a width of about 50 micrometers) may enable the rigid flex PCB to operate at a speed equal to or greater than about 25 gigabits per second per channel in the optics products.

As data rates for electronic and optoelectronic systems continue to increase, further techniques may be required to reduce the parasitic capacitance and parasitic inductance that can compromise the signal integrity of the transmissions. Accordingly, reductions in these parasitic reactances may allow increases in the transmission frequencies while preserving the integrity of the transmissions.

As demands for bandwidth increase, optoelectronic modules become more densely populated with transmit and receive circuitry. Further, the transmit and receive circuits may interface, as stated, with a host system (not shown) using a connector. The signal density of the transmit and receive circuitry results in the need to provide the interface to the host system using contacts on both sides of the connector on the printed circuit board.

Accordingly, signals generated using circuits on one side of the printed circuit boards necessarily need to be routed through the printed circuit board using vias to the other side of the printed circuit board to route to contacts 108 on the other side of the rigid flex PCB. When the signals routed from one side of the printed circuit board to the other side of the printed circuit board are high-speed signals, the vias may introduce capacitance and mutual inductance that distorts the high-speed signal. Accordingly, reducing the impedance mismatching of the via between the external high-speed cap layers 113 would improve the signal integrity for those signals that are routed to an opposite side of the printed circuit board.

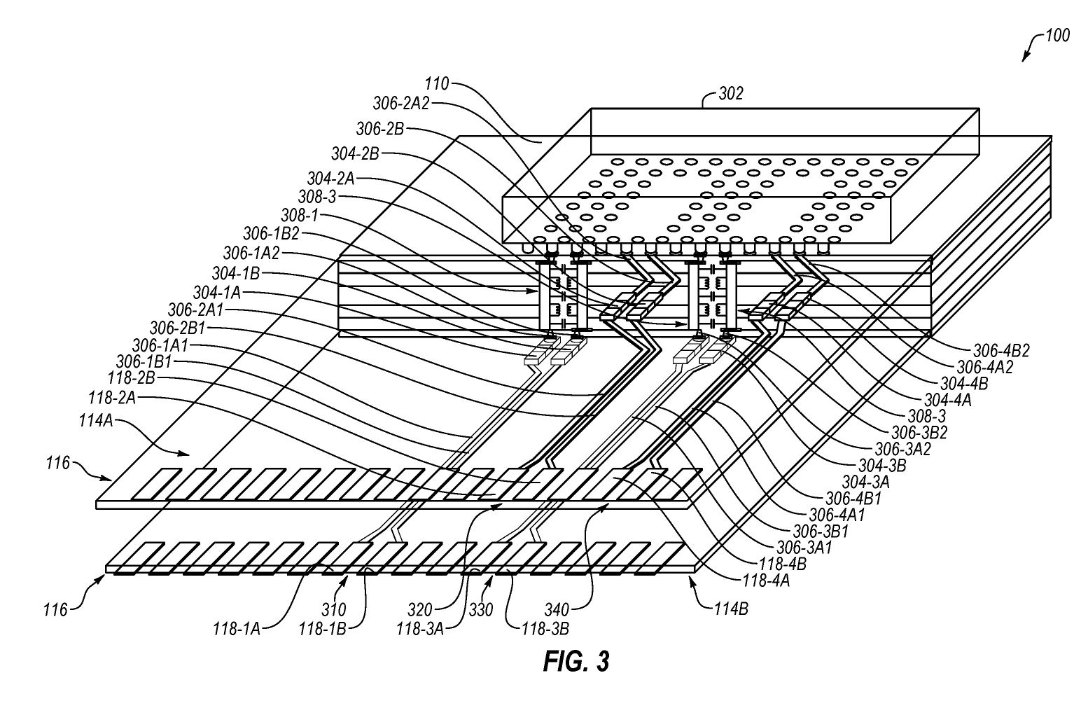

FIG. 3 illustrates a perspective view of a portion of the optoelectronic module 100 of FIG. 1. The optoelectronic module 100 may include various components that may be surface mounted to the rigid flex PCB 110. The components may be specific to the transmitter and/or the receiver. While FIG. 3 illustrates a component 302 specific to a transmitter, the processes and structures described herein also find application for both transmitted and received high-speed signals.

By way of example, a component 302 may be a driver integrated circuit configured for handling one or multiple channels of transmit signals. Each channel may be configured as a differential channel comprised of a differential signal pair. In FIG. 3, the component 302 is illustrated, for example, as being configured to support four separate transmit channels (e.g., Channel-1 through Channel-4).

Some of the channels are configured for coupling to a host device at a top-side or face 114A and other channels are configured for coupling to the host device at a bottom-side (opposite) or face 114B. For example, a first channel (Channel-1) 310 and a third channel (Channel-3) 330 are illustrated as coupling to contacts 118 on the bottom-side or face 114B of the connector 106. Specifically, the first channel 310 couples to first differential contacts 118-1A and 118-1B and the third channel 330 couples to the third differential contacts 118-3A and 118-3B, all on the bottom-side or face 114B of the connector 116. Similarly, the second channel 320 couples to second differential contacts 118-2A and 118-2B and the fourth channel 340 couples to the fourth differential contacts 118-4A and 118-4B, all on the top-side or face 114A of the connector 116.

Each of the channels is also routed through blocking capacitors for blocking DC voltages from creating an undesirable offset in the differential signal. The blocking capacitors are preferably mounted on the same side of the rigid flex PCB 110 as the contacts for the driving circuit. For example, blocking capacitors 304-2 and 304-4 for respective second channel 320 and fourth channel 340 are illustrated as being mounted on a top-side or face 114A while blocking capacitors 304-1 and 304-3 for respective first channel 310 and third channel 330 are illustrated as being mounted on a bottom-side or face 114B.

Specifically on face 114A, the second channel 320 includes blocking capacitors 304-2A and 304-2B respectively electrically connected in series with the traces 306-2A and 306-2B. More specifically, the blocking capacitor 304-2A is electrically connected between the trace 306-2A1 and 306-2A2 and blocking capacitor 304-2B may be electrically connected between the trace 306-2B1 and 306-2B2. Similarly, the fourth channel 340 includes blocking capacitors 304-4A and 304-4B respectively electrically connected in series with the traces 306-4A and 306-4B. More specifically, the blocking capacitor 304-4A may be electrically connected between the trace 306-4A1 and 306-4A2 and blocking capacitor 304-4B may be electrically connected between the trace 306-4B1 and 306-4B2.

Specifically on face 114B, the first channel 310 includes blocking capacitors 304-1A and 304-1B respectively electrically connected in series with the traces 306-1A and 306-1B. More specifically, the blocking capacitor 304-1A is electrically connected between the trace 306-1A1 and 306-1A2 (illustrated as a blind via and further described below) and blocking capacitor 304-1B may be electrically connected between the trace 306-1B1 and 306-1B2 (illustrated as a blind via and further described below). Similarly, the third channel 330 includes blocking capacitors 304-3A and 304-3B respectively electrically connected in series with the traces 306-3A and 306-3B. More specifically, the blocking capacitor 304-3A may be electrically connected between the trace 306-3A1 and 306-3A2 (illustrated as a blind via and further described below) and blocking capacitor 304-3B may be electrically connected between the trace 306-3B1 and 306-3B2 (illustrated as a blind via and further described below).

As stated, routing of channels to an opposite side of the printed circuit board using vias results in undesired mutual inductance and impedance mismatch for signals transmitted over a differential channel. It would be advantageous to provide impedance matching for via structures conveying a high-speed signal from one side of a printed circuit board to the other side of the printed circuit board.

Continuing with FIG. 3, the rigid flex PCB 110 further includes tunable differential vias 308. More specifically, the signals on the first channel 310 pass through tunable differential vias 308-1 which conductively passes signals from one side or face 114 of the rigid flex PCB 110 to the other side or face 114 of the rigid flex PCB 110. Similarly, the signals on the third channel 330 pass through tunable differential vias 308-3 which conductively passes signals from one side or face 114 of the rigid flex PCB 110 to the other side or face 114 of the rigid flex PCB 110.

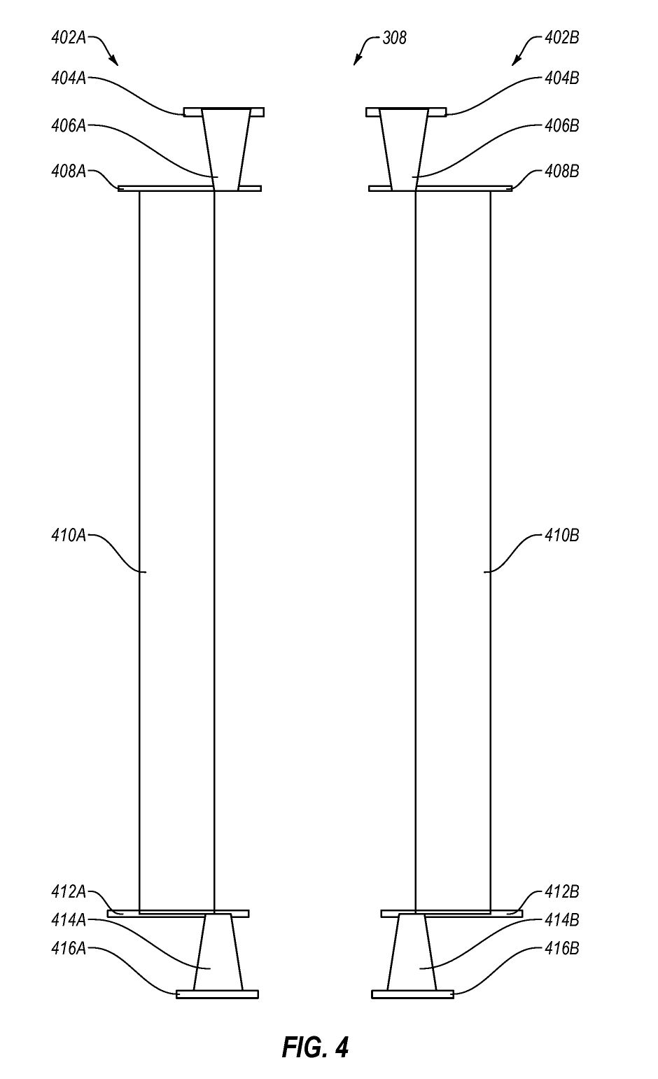

FIG. 4 is a cross-sectional view of tunable differential vias. The tunable differential via 308 includes a first and second tunable via circuits 402. The first tunable via circuit 402-A conducts a first one of the differential signals through the rigid flex PCB 110 and the second tunable via circuit 402-B conducts a second one of the differential signals through the rigid flex PCB 110. At least one of the tunable via circuits 402 may include a combination of different vias allowing spatial separation from the other one of the tunable via circuits 402 for enabling tunability within the tunable differential vias 308. By way of example, FIG. 4 illustrates both tunable via circuits 402-A and 402-B as being individually spatially adjustable.

The tunable via circuit 402 may include a first shared pad 404 formed on a first conductive layer 140 (FIG. 1) of the cap layer 113A (FIG. 1). The first shared pad 404 may be a pad that is shared by both a component 302 (FIG. 3) and a first blind via 406. The first blind via 406 couples the first conductive layer 140 through a dielectric 116A to a second conductive layer 142 (FIG. 1). The first shared pad 404 may be arranged in, for example, a ball grid array (BGA) pattern for coupling to a pad on a component 302, or the first shared pad 404 may be configured to receive a wire bond from a pad on a component 302. Further, the interconnection impedance may be reduced by sharing a pad between multiple structures rather than routing a trace conductor between two spatially separated dedicated pads.

The tunable circuit 402 may further include a second shared pad 408 formed from the second conductive layer 142 (FIG. 1) and configured to electrically connect together both the first blind via 406 and a buried via 410. The second shared pad 408 may be varied in size to accommodate spatial separation between buried via 410A and buried via 410B thereby creating a tunable impedance in the tunable differential via 308. The buried via 410 may be formed using various means including mechanical drilling through the core layers 112 (FIG. 2).

The buried via 410 may further electrically connect to a third shared pad 412. The third shared pad 412 may be formed on a third conductive layer 144 (FIG. 2) of the core layers 112. The third shared pad 412 may be a pad that is shared by both the buried via 410 and a second blind via 414. Like the second shared pad 408, the third shared pad 412 may be varied in size to accommodate spatial separation between buried via 410A and buried via 410B thereby creating a tunable impedance in the tunable differential via 308.

The tunable via circuit 402 may further include a second blind via 414. The second blind via 414 couples a third conductive layer 144 through a dielectric 116B to a fourth shared pad 416 formed on a fourth conductive layer 146 (FIG. 1). The fourth shared pad 416 may be arranged in, for example, as a surface mount pad for coupling to a terminal of a blocking capacitor 304. Further, the interconnection impedance may be reduced by sharing a pad between multiple structures rather than routing a trace conductor between two spatially separated dedicated pads.

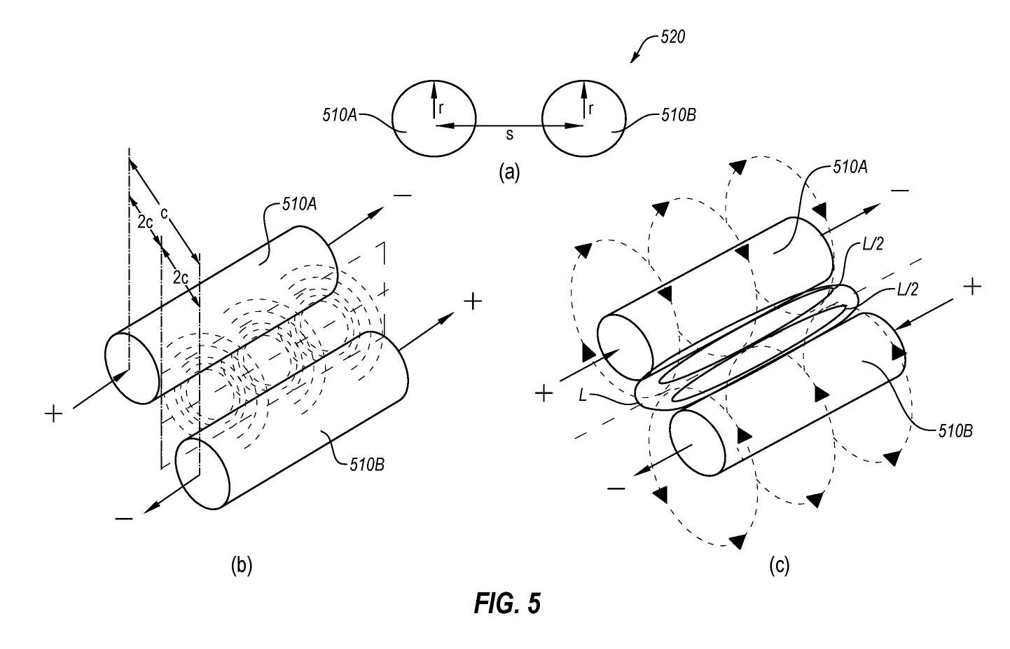

FIG. 5 illustrates an example geometry of the electromagnetic field relationship and method of calculating the resultant impedance for the tunable differential vias. The buried vias 410 of FIG. 4 are represented by “twin-rods” 510A and 510B, hereinafter referred to as buried vias. A cross-section 520 illustrates an orientation of the buried vias 510A and 510B, each with a radius r and spaced apart by a distance s. Those of ordinary skill in the art appreciate that currents passing through the buried vias 510 generate the corresponding fields as illustrated in FIG. 5.

The following equation forms the basis for a calculation of the capacitance in Farads between the buried vias 510, where

Ctwin=Capacitance between twin-rods—F

Ltwin=Inductance between twin-rods—H

Zdiff=Differential Impedance of twin-rods—Ω

Dk=Dielectric constant of material

Len=Length of the rods

r=Radius of the rods

s=Space between the rods

$$Ctwin = \frac{7.06 E - 13}{In ( \frac{s}{2 r} [ 1 + \sqrt{1 - {( \frac{2 r}{s} )}^{2} ] )}} \times Dk \times Len$$

The following equation forms the basis for a calculation of the inductance in Henrys between the buried vias 510.

$$Ltwin = 10.16 E - 9 * In ( \frac{s}{2 r} + \sqrt{{( \frac{s}{2 r} )}^{2}} - 1 ) * Len$$

The differential impedance between the buried vias may then be calculated by the following equation.

$$Zdiff = \sqrt{\frac{Ltwin}{Ctwin}} = \sqrt{\frac{10.16 E - 9 * In ( \frac{s}{2 r} + \sqrt{{( \frac{s}{2 r} )}^{2}} - 1 ) * Len}{\frac{7.06 E - 13}{In ( \frac{s}{2 r} [ 1 + \sqrt{1 - {( \frac{2 r}{s} )}^{2}} ] )} \times Dk \times Len}}$$

This equation then simplifies to the following equation.

$$Zdiff = \frac{120}{\sqrt{Dk}} \times In ( \frac{s}{2 r} + \sqrt{{( \frac{s}{2 r} )}^{2}} - 1 )$$

By way of an example, when s is 0.6 mm and r is equal to 0.15 mm, and when the dielectric constant Dk is equal to 4.58 and the length Len is equal to 6 mm, then the differential impedance Zdiff calculates to equal about 99.1403135 ohms.

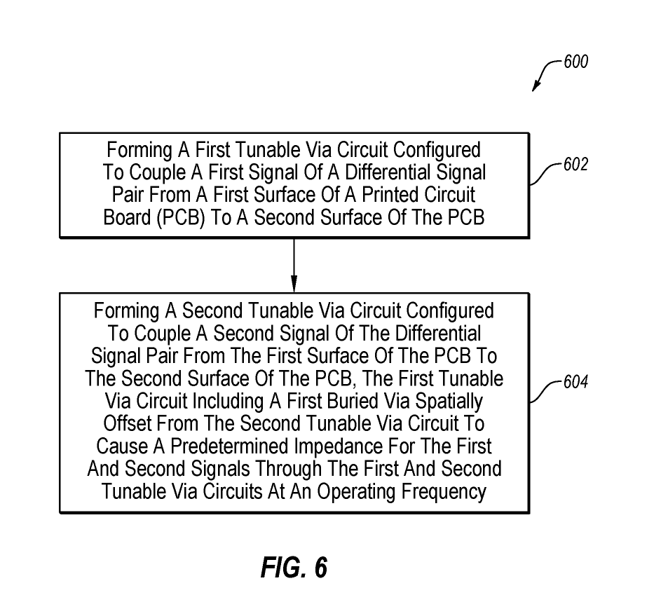

FIG. 6 is a flowchart of an example method of manufacturing the example tunable differential vias. The method 600 may be implemented, in some embodiments, to manufacture a circuit, such as a rigid flex PCB including the tunable differential vias, as described with reference to FIGS. 1-5. It will be appreciated that the tunable differential vias formed in a rigid flex PCB may be manufactured using a method other than the one disclosed here.

As shown in block 602, the method may include forming a first tunable via circuit configured to couple a first signal of a differential signal pair from a first outer surface of a printed circuit board (PCB) to a second outer surface of the PCB.

As shown in block 604, the method may include forming a second tunable via circuit configured to couple a second signal of the differential signal pair from the first outer surface of the PCB to the second outer surface of the PCB. Furthermore, the first tunable via circuit may include a first buried via spatially offset from the second tunable via circuit to cause a predetermined impedance for the first and second signals through the first and second tunable via circuits at an operating frequency.

One skilled in the art will appreciate that, for this and other processes and methods disclosed herein, the functions performed in the processes and methods may be implemented in differing order. Furthermore, the outlined steps and operations are only provided as examples, and some of the steps and operations may be optional, combined into fewer steps and operations, or expanded into additional steps and operations without detracting from the essence of the disclosed embodiments.

The present invention may be embodied in other specific forms without departing from its spirit or essential characteristics. The described embodiments are to be considered in all respects only as illustrative and not restrictive. The scope of the invention is, therefore, indicated by the appended claims rather than by the foregoing description. All changes which come within the meaning and range of equivalency of the claims are to be embraced within their scope.

1. A circuit, comprising:
a first tunable via circuit configured to couple a first signal of a differential signal pair from a first outer surface of a printed circuit board (PCB) to a second outer surface of the PCB; and
a second tunable via circuit configured to couple a second signal of the differential signal pair from the first outer surface of the PCB to the second outer surface of the PCB,
the first tunable via circuit including a first buried via spatially offset from the second tunable via circuit to cause a predetermined impedance for the first and second signals through the first and second tunable via circuits at an operating frequency.

2. The circuit of claim 1, wherein the first tunable via circuit further comprises a first blind via between the first outer surface of the PCB and the first buried via.

3. The circuit of claim 2, wherein the first tunable via circuit further comprises a first shared pad formed on the first outer surface of the PCB, the first shared pad configured to electrically connect a first pin of an electronic component with the first blind via.

4. The circuit of claim 2, wherein the first tunable via circuit further comprises a second blind via between the second outer surface of the PCB and the first buried via.

5. The circuit of claim 4, wherein the first tunable via circuit further comprises a second shared pad formed on the second outer surface of the PCB, the second shared pad configured to electrically connect a first blocking capacitor with the second blind via.

6. The circuit of claim 4, wherein the second tunable via circuit includes a second buried via spatially offset from the first buried via to cause the predetermined impedance for the first and second signals through the first and second tunable via circuits at an operating frequency.

7. The circuit of claim 6, wherein the second tunable via circuit further comprises:
a third blind via between the first outer surface of the PCB and the second buried via; and
a fourth blind via between the second outer surface of the PCB and the second buried via.

8. The circuit of claim 7, wherein,
the first tunable via circuit further comprises:
a first shared pad formed on the first outer surface of the PCB, the first shared pad configured to electrically connect a first pin of an electronic component with the first blind via, and
a second shared pad formed on the second outer surface of the PCB, the second shared pad configured to electrically connect a first blocking capacitor with the second blind via; and
the second tunable via circuit further comprises:
a third shared pad formed on the first outer surface of the PCB, the third shared pad configured to electrically connect a second pin of the electronic component with the third blind via, and
a fourth shared pad formed on the second outer surface of the PCB, the fourth shared pad configured to electrically connect a second blocking capacitor with the fourth blind via.

9. A circuit, comprising:
a multilayer rigid flex PCB including a first cap layer forming a first outer surface of the multilayer rigid flex PCB and a second cap layer forming a second outer surface of the multilayer rigid flex PCB; and
tunable differential vias formed between the first and second outer surfaces of the multilayer rigid flex circuit, the tunable differential vias including:
a first tunable via circuit configured to couple a first signal of a differential signal pair from the first outer surface of the multilayer rigid flex PCB to a second outer surface of the multilayer rigid flex PCB; and
a second tunable via circuit configured to couple a second signal of the differential signal pair from the first outer surface of the multilayer rigid flex PCB to the second outer surface of the multilayer rigid flex PCB,
the first tunable via circuit including a first buried via spatially offset from the second tunable via circuit to cause a predetermined impedance for the first and second signals through the first and second tunable via circuits at an operating frequency.

10. The circuit of claim 9, wherein the second tunable via circuit includes a second buried via spatially offset from the first buried via to cause the predetermined impedance for the first and second signals through the first and second tunable via circuits at an operating frequency.

11. The circuit of claim 10, wherein the first tunable via circuit further comprises a first blind via through the first cap layer and between the first outer surface of the multilayer rigid flex PCB and the first buried via and a second blind via through the second cap layer and between the second outer surface of the multilayer rigid flex PCB and the first buried via, and the second tunable via circuit further comprises a third blind via through the first cap layer and between the first outer surface of the multilayer rigid flex PCB and the second buried via and a fourth blind via through the second cap layer and between the second outer surface of the multilayer rigid flex PCB and the second buried via.

12. The circuit of claim 11, wherein,
the first tunable via circuit further comprises:
a first shared pad formed on the first outer surface of the multilayer rigid flex PCB, the first shared pad configured to electrically connect a first pin of an electronic component with the first blind via, and
a second shared pad formed on the second outer surface of the multilayer rigid flex PCB, the second shared pad configured to electrically connect a first blocking capacitor with the second blind via; and
the second tunable via circuit further comprises:
a third shared pad formed on the first outer surface of the multilayer rigid flex PCB, the third shared pad configured to electrically connect a second pin of the electronic component with the third blind via, and
a fourth shared pad formed on the second outer surface of the multilayer rigid flex PCB, the fourth shared pad configured to electrically connect a second blocking capacitor with the fourth blind via.

13. An optoelectronic module, comprising:
an optical transmitter;
an optical receiver;
a circuit including:
a printed circuit board (PCB) including:
a first tunable via circuit configured to couple a first signal of a differential signal pair from a first outer surface of the PCB to a second outer surface of the PCB; and
a second tunable via circuit configured to couple a second signal of the differential signal pair from the first outer surface of the PCB to the second outer surface of the PCB,
the first tunable via circuit including a first buried via spatially offset from the second tunable via circuit to cause a predetermined impedance for the first and second signals through the first and second tunable via circuits at an operating frequency.

14. The optoelectronic module of claim 13, wherein the second tunable via circuit includes a second buried via spatially offset from the first buried via to cause the predetermined impedance for the first and second signals through the first and second tunable via circuits at an operating frequency.

15. The optoelectronic module of claim 14, wherein the first tunable via circuit further comprises a first blind via between the first outer surface of the PCB and the first buried via, and the second tunable via circuit further comprises a second blind via between the first outer surface of the PCB and the second buried via.

16. The optoelectronic module of claim 15, wherein the first blind via and the second blind via respectively couple to a first shared pad and a second shared pad on the first outer surface and the first shared pad and the second shared pad couple to a differential pair signal from one of the optical transmitter and optical receiver.

17. The optoelectronic module of claim 16, wherein the first tunable via circuit further comprises a third blind via between the second outer surface of the PCB and the first buried via, and the second tunable via circuit further comprises a fourth blind via between the second outer surface of the PCB and the second buried via.

18. The optoelectronic module of claim 17, wherein the third blind via and the fourth blind via respectively couple to a third shared pad and a fourth shared pad on the second outer surface and the third shared pad and the fourth shared pad respectively couple to a first blocking capacitor and a second blocking capacitor on the second outer surface of the PCB.

19. (canceled)

20. (canceled)
